(19) United States
(12) Patent Application Publication
(10) Pub. No.: US 2026/0186402 A1
(43) Pub. Date: Jul. 2, 2026

(54) METHOD AND SYSTEM FOR GENERATING DROP PATTERNS, SHAPING SYSTEM, AND METHOD OF MAKING AN ARTICLE

(71) Applicant: CANON KABUSHIKI KAISHA, Tokyo (JP)

(72) Inventors: SHIUAN-HAUR SU, Cupertino, CA (US); YOKO TANAKA, Oyama-shi (JP); SHINGO ISHIDA, Utsunomiya-shi (JP); WEI ZHANG, Austin, TX (US); HUMBERTO BOCANEGRA EVANS, Austin, TX (US)

(21) Appl. No.: 19/003,956

(22) Filed: Dec. 27, 2024

(51) Int. Cl. G03F 7/00

(52) U.S. Cl. CPC G03F 7/0002

(57) ABSTRACT

A method of generating a drop pattern includes receiving an initial drop pattern based on a volume requirement map, receiving or determining a location of a centroid of a feature within the volume requirement map, receiving or determining a volume differential between a fill volume requirement of the feature and a fill volume associated with dispensing drops according to the initial drop pattern, identifying, among the drop positions of the initial drop pattern, a drop position that is closest to the location of the centroid, determining a distance between the identified drop position and the location of the centroid, and generating the drop pattern by: changing a volume of a drop associated with the identified drop position of the initial drop pattern based on the volume differential, and changing the identified drop position of the initial drop pattern to a different drop position based on the determined distance.

### BACKGROUND

### Technical Field

The present disclosure relates to photomechanical shaping systems (e.g., Nanoimprint Lithography and Inkjet Adaptive Planarization). In particular, the disclosure relates to a drop pattern forming method for generating a drop pattern and dispensing drops according to the generated drop pattern as used in photomechanical shaping.

### Description of the Related Art

Nano-fabrication includes the fabrication of very small structures that have features on the order of 100 nanometers or smaller. One application in which nano-fabrication has had a sizeable impact is in the fabrication of integrated circuits. The semiconductor processing industry continues to strive for larger production yields while increasing the circuits per unit area formed on a substrate. Improvements in nano-fabrication include providing greater process control and/or improving throughput while also allowing continued reduction of the minimum feature dimensions of the structures formed.

One nano-fabrication technique in use today is commonly referred to as nanoimprint lithography. Nanoimprint lithography is useful in a variety of applications including, for example, fabricating one or more layers of integrated devices by shaping a film on a substrate. Examples of an integrated device include but are not limited to CMOS logic, microprocessors, NAND Flash memory, NOR Flash memory, DRAM memory, MRAM, 3D cross-point memory, Re-RAM, Fe-RAM, STT-RAM, MEMS, and the like. Exemplary nanoimprint lithography systems and processes are described in detail in numerous publications, such as U.S. Pat. Nos. 8,349,241, 8,066,930, and 6,936,194, all of which are hereby incorporated by reference herein.

The nanoimprint lithography technique disclosed in each of the aforementioned patents describes the shaping of a film on a substrate by the formation of a relief pattern in a formable material (polymerizable) layer. The shape of this film may then be used to transfer a pattern corresponding to the relief pattern into and/or onto an underlying substrate.

The shaping process uses a template spaced apart from the substrate. The formable material is applied onto the substrate. The template is brought into contact with the formable material that may have been deposited as a drop pattern using the formable material to spread and fill the space between the template and the substrate. The template may be used to imprint full fields and/or partial fields on the substate. The formable material is solidified to form a film that has a shape (pattern) conforming to a shaping surface of the template. After solidification, the template is separated from the solidified layer such that the template and the substrate are spaced apart.

The substrate and the solidified layer may then be subjected to known steps and processes for device (article) fabrication, including, for example, curing, oxidation, layer formation, deposition, doping, planarization, etching, formable material removal, dicing, bonding, and packaging, and the like. For example, the pattern on the solidified layer may be subjected to an etching process that transfers the pattern into the substrate.

U.S. Pat. No. 11,556,055 (hereafter “the '055 patent”) discloses a method for generating a drop pattern for imprint lithography, which is hereby incorporated by reference herein in its entirety. In the method of the '055 patent, as well as in other disclosed drop pattern generating methods, when drops are dispensed according to the drop patterns generated by the disclosed methods, in many cases the dispensed drops take a relatively long time (e.g., 0.5 seconds, 30 seconds 2s) to fill relatively large (e.g., 0.01 to 10 picoliters fill volume depending on the drop volume) features and/or alignment marks. Longer fill times negatively effects production time (i.e., throughput). Thus, there is a need for a method of generating drop patterns that reduces the fill time of relatively large features/marks when drops are dispend according to the drop pattern.

### SUMMARY

A method of generating a drop pattern includes receiving an initial drop pattern including a plurality of drop positions representing dispensing locations for a plurality of drops of equal volume, wherein the initial drop pattern is based on a volume requirement map; receiving or determining a location of a centroid of a feature within the volume requirement map; receiving or determining a volume differential between a fill volume requirement of the feature and a fill volume associated with dispensing the plurality of drops according to the initial drop pattern; identifying, among the plurality of drop positions of the initial drop pattern, a drop position that is closest to the location of the centroid; determining a distance between the identified drop position and the location of the centroid; and generating the drop pattern by: changing a volume of a drop associated with the identified drop position of the initial drop pattern based on the volume differential; and changing the identified drop position of the initial drop pattern to a different drop position based on the determined distance.

A shaping system includes a first chuck configured to hold a template or superstrate; a second chuck configured to hold a substrate; a processor configured to: receive an initial drop pattern including a plurality of drop positions representing dispensing locations for a plurality of drops of equal volume, wherein the initial drop pattern is based on a volume requirement map; receive or determine a location of a centroid of a feature within the volume requirement map; receive or determine a volume differential between a fill volume requirement of the feature and a fill volume associated with dispensing the plurality of drops according to the initial drop pattern; identify, among the plurality of drop positions of the initial drop pattern, a drop position that is closest to the location of the centroid; determine a distance between the identified drop position and the location of the centroid; and generate the drop pattern by: changing a volume of a drop associated with the identified drop position of the initial drop pattern based on the volume differential; and changing the identified drop position of the initial drop pattern to a different drop position based on the determined distance; a fluid dispenser configured to dispense drops of formable material on the substrate in accordance with the generated drop pattern; a positioning system configured to bring a template or a superstrate into contact with the formable material; and a curing system configured to expose the formable material under the template or superstrate to actinic radiation.

A method of making an article includes receiving an initial drop pattern including a plurality of drop positions representing dispensing locations for a plurality of drops of equal volume, wherein the initial drop pattern is based on a volume requirement map; receiving or determining a location of a centroid of a feature within the volume requirement map; receiving or determining a volume differential between a fill volume requirement of the feature and a fill volume associated with dispensing the plurality of drops according to the initial drop pattern; identifying, among the plurality of drop positions of the initial drop pattern, a drop position that is closest to the location of the centroid; determining a distance between the identified drop position and the location of the centroid; and generating the drop pattern by: changing a volume of a drop associated with the identified drop position of the initial drop pattern based on the volume differential; and changing the identified drop position of the initial drop pattern to a different drop position based on the determined distance; dispensing drops of formable material onto a substrate according to the modified drop pattern; bringing a template or superstrate into contact with the formable material; exposing the formable material under the template or superstrate to actinic radiation; processing the substrate; and forming the article from the processed substrate.

These and other aspects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention, and are therefore not to be considered limiting of its scope, for the invention may admit to other equally effective embodiments.

FIG. 1 is an illustration of an exemplary nanoimprint lithography system having a template with a mesa spaced apart from a substrate as used in an embodiment.

FIGS. 2A-B are illustrations of exemplary templates that may be used in an embodiment.

FIG. 3 is a flowchart illustrating an exemplary imprinting method as used in an embodiment.

FIG. 4 is a flowchart illustrating an exemplary drop pattern generation method as used in an embodiment.

FIG. 5 is a schematic representation of an example initial drop pattern in accordance with an example embodiment.

FIG. 6 is a schematic representation of the example initial drop pattern with an identified large feature/mark in accordance with an example embodiment.

FIG. 7 is a schematic representation of the example initial drop pattern with an identified centroid of the large feature/mark in accordance with an example embodiment.

FIG. 8 is a schematic representation of the example initial drop pattern where the distance between nearby drop positions and the centroid are indicated in accordance with an example embodiment.

FIG. 9 is a schematic representation of the example initial drop pattern where the closest drop position to the centroid has been identified in accordance with an example embodiment.

FIG. 10 is a schematic representation of a modified drop pattern where the volume associated with the identified drop position has been changed in accordance with an example embodiment.

FIG. 11 is a schematic representation of an example generated drop pattern where the distance of the identified drop position from the centroid has been changed in accordance with an example embodiment.

FIG. 12 shows is a schematic representation of an example generated drop pattern in which multiple drop positions around the same large feature/mark have been changed relative to the initial drop pattern and whose associated drop volume has been increased in accordance with an example embodiment.

FIG. 13 shows is a schematic representation of an example generated drop pattern in which multiple drop positions around multiple large features/marks have been changed relative to the initial drop pattern and whose associated drop volume has been increased in accordance with an example embodiment.

FIG. 14 is a chart showing the filling performance of drops dispensed according to the initial drop pattern as compared to filling performance of drops dispensed according to the modified drop pattern of FIG. 11 in accordance with an example embodiment.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

Throughout this disclosure, reference is made primarily to nanoimprint lithography, which uses the above-mentioned patterned template to impart a pattern onto formable liquid. However, in an alternative embodiment, the template is featureless in which case a planar surface may be formed on the substrate. In such embodiments where a planar surface is formed, the formation process is referred to as planarization and a featureless template is referred to as a superstrate. Thus, throughout this disclosure, whenever nanoimprint lithography is mentioned, it should be understood that the disclosure is applicable to planarization.

### Nanoimprint System (Shaping System)

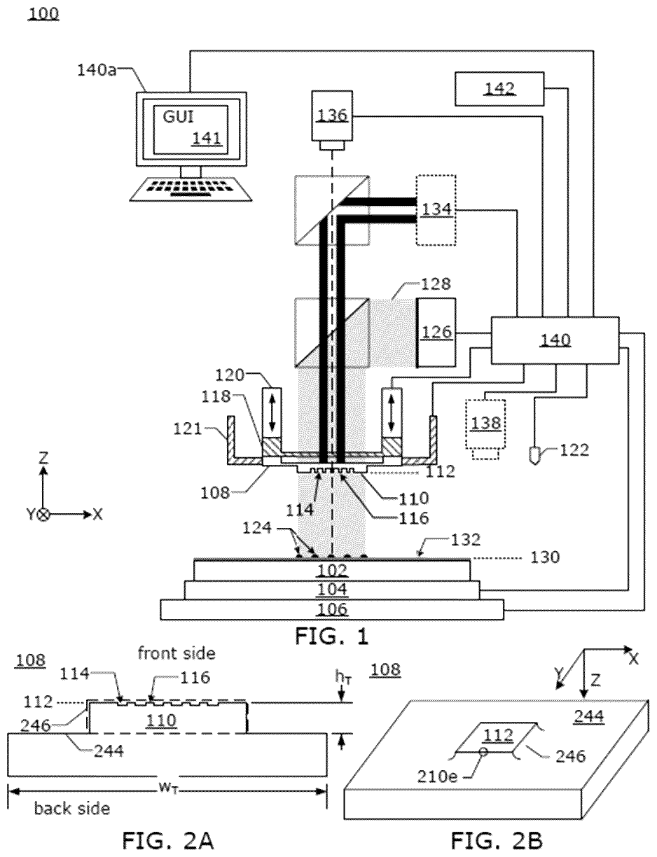

FIG. 1 is an illustration of a shaping system 100 (for example a nanoimprint lithography system or inkjet adaptive planarization system) in which an embodiment may be implemented. The shaping system 100 is used to produce an imprinted (shaped) film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the positional axes x, y, and z, and rotational axes θ, ψ, and φ. The substrate positioning stage 106, the substrate 102, and the substrate chuck 104 may also be positioned on a base (not shown). The substrate positioning stage may be a part of a positioning system. In an alternative embodiment, the substrate chuck 104 may be attached to the base.

Spaced-apart from the substrate 102 is a template 108 (also referred to as a superstrate). The template 108 may include a body having a mesa (also referred to as a mold) 110 extending towards the substrate 102 on a front side of the template 108. The mesa 110 may have a shaping surface 112 thereon also on the front side of the template 108. The shaping surface 112, also known as a patterning surface, is the surface of the template that shapes the formable material 124. The mesa, and more particularly, the shaping surface 112, has a surface area facing the substrate 102. In an embodiment, the shaping surface 112 is planar and is used to planarize the formable material. Alternatively, the template 108 may be formed without the mesa 110, in which case the surface of the template facing the substrate 102 is equivalent to the mesa 110 and the shaping surface 112 is that surface of the template 108 facing the substrate 102.

The template 108 may be formed from such materials including, but not limited to, fused-silica, quartz, silicon, organic polymers, siloxane polymers, borosilicate glass, fluorocarbon polymers, metal, hardened sapphire, and/or the like. The shaping surface 112 may have features defined by a plurality of spaced-apart template recesses 114 and/or template protrusions 116. The shaping surface 112 defines a pattern that forms the basis of a pattern to be formed on the substrate 102. In an alternative embodiment, the shaping surface 112 is featureless in which case a planar surface is formed on the substrate. In an alternative embodiment, the shaping surface 112 is featureless and the same size as the substrate and a planar surface is formed across the entire substrate.

The template 108 may be coupled to a template chuck 118. The template chuck 118 may be, but is not limited to, vacuum chuck, pin-type chuck, groove-type chuck, electrostatic chuck, electromagnetic chuck, and/or other similar chuck types. The template chuck 118 may be configured to apply stress, pressure, and/or strain to template 108 that varies across the template 108. The template chuck 118 may include a template magnification control system 121. The template magnification control system 121 may include piezoelectric actuators (or other actuators) which can squeeze and/or stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to a shaping head 120 which is a part of the positioning system. The shaping head 120 may be moveably coupled to a bridge. The shaping head 120 may include one or more actuators such as voice coil motors, piezoelectric motors, linear motor, nut and screw motor, etc., which are configured to move the template chuck 118 relative to the substrate in at least the z-axis direction, and potentially other directions (e.g., positional axes x, and y, and rotational axes θ, ψ, and φ).

The shaping system 100 may further comprise a fluid dispenser 122. The fluid dispenser 122 may also be moveably coupled to the bridge. In an embodiment, the fluid dispenser 122 and the shaping head 120 share one or more or all of the positioning components. In an alternative embodiment, the fluid dispenser 122 and the shaping head 120 move independently from each other. The fluid dispenser 122 may be used to deposit liquid formable material 124 (e.g., polymerizable material) onto the substrate 102 in a drop pattern. Additional formable material 124 may also be added to the substrate 102 using techniques, such as, drop dispense, spin-coating, dip coating, chemical vapor deposition (CVD), physical vapor deposition (PVD), thin film deposition, thick film deposition, and/or the like prior to the formable material 124 being deposited onto the substrate 102. The formable material 124 may be dispensed upon the substrate 102 before and/or after a desired volume is defined between the shaping surface 112 and the substrate 102 depending on design considerations. The formable material 124 may comprise a mixture including a monomer as described in U.S. Pat. Nos. 7,157,036 and 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that induces a phase change in the liquid formable material into a solid material whose top surface is determined by the shape of the shaping surface 112. The curing system may include at least a radiation source 126 that directs actinic energy along an exposure path 128. The shaping head and the substrate positioning stage 106 may be configured to position the template 108 and the substrate 102 in superimposition with the exposure path 128. The radiation source 126 sends the actinic energy along the exposure path 128 after the template 108 has contacted the formable material 124. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124. In an embodiment, the actinic energy may be directed through both the template chuck 118 and the template 108 into the formable material 124 under the template 108. In an embodiment, the actinic energy produced by the radiation source 126 is UV light that induces polymerization of monomers in the formable material 124.

The shaping system 100 may further comprise a field camera 136 that is positioned to view the spread of formable material 124 after the template 108 has contacted the formable material 124. FIG. 1 illustrates an optical axis of the field camera's imaging field as a dashed line. As illustrated in FIG. 1 the shaping system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. Thus, the field camera may also be referred to as a spread camera. The optical axis of the field camera 136 as illustrated in FIG. 1 is straight but may be bent by one or more optical components. The field camera 136 may include one or more of: a CCD; a sensor array; a line camera; and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting (shaping) process. The field camera 136 may also be configured to measure interference fringes, which change as the formable material spreads 124 between the gap between the shaping surface 112 and the substrate surface 130. The shape of interference fringes can be dependent upon deformation of the shaping surface 112 relative to a shape of the substrate surface 130.

The shaping system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as lenses, mirrors, optical diaphragms, apertures, filters, prisms, polarizers, windows, adaptive optics, and/or light sources. The droplet inspection system 138 may be positioned to inspect droplets prior to the shaping surface 112 contacting the formable material 124 on the substrate 102. In an alternative embodiment, the field camera 136 may be configured as a droplet inspection system 138 and used prior to the shaping surface 112 contacting the formable material 124.

The shaping system 100 may further include a thermal radiation source 134 which may be configured to provide a spatial distribution of thermal radiation to one or both of the template 108 and the substrate 102. The thermal radiation source 134 may include one or more sources of thermal electromagnetic radiation that will heat up one or both of the substrate 102 and the template 108 and does not cause the formable material 124 to solidify. The thermal radiation source 134 may include a SLM such as a digital micromirror device (DMD), Liquid Crystal on Silicon (LCoS), Liquid Crystal Device (LCD), etc., to modulate the spatio-temporal distribution of thermal radiation. The shaping system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation source 134 may send the thermal radiation along a thermal radiation path (which in FIG. 1 is illustrated as 2 thick dark lines) after the template 108 has contacted the formable material 124. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation source 134 is underneath the substrate 102, and thermal radiation path is not combined with the actinic radiation and the visible light.

The shaping system 100 may further include a light source 135 which may emit measurement light 137. The light source 135 may be configured to emit visible light toward the substrate and template when the template and the substrate are near each other, as will be discussed in more detail below. The light 137 may be 470 nm light, for example. The measurement light 137 may be monochromatic. The light source 135 may be an array of light emitting diodes. The light source 135 may include one or more lasers. While the light source 135 is shown as a separate element in FIG. 1, in another example embodiment the light source 135 may be integrated into the thermal radiation source 134 or integrated into the radiation source 126. The field camera/spread camera 136 may be configured to capture images of the template and substrate as the measurement light 137 is reflected by the template and substrate as discussed below. The shaping system 100 may include one or more optical components which guide measurement light 137 through the shaping surface 112, reflects off the substrate surface 130 back through the shaping surface 112 and is received by the field camera 136. The one or more optical components can also guide measurement light 137 that is reflected off the shaping surface 112 to the field camera 136. Examples of the one or more optical components include but are not limited to: lenses, mirrors, optical diaphragms, apertures, filters, optical combiners, optical splitters, prisms, polarizers, windows, adaptive optics, etc.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, drop dispense, slot dispense, etc. In an embodiment, the substrate 102 may be a semiconductor wafer, a glass wafer, a sapphire wafer, or some other material. In another embodiment, the substrate 102 may be a blank template (replica blank) that may be used to create a daughter template after being imprinted.

The shaping system 100 may include an imprint field atmosphere control system such as gas and/or vacuum system, an example of which is described in U.S. Patent Publication No. 2010/0096764 and U.S. Pat. No. 10,895,806 which are hereby incorporated by reference. The gas and/or vacuum system may include one or more of: pumps, valves, solenoids, gas sources, gas tubing, etc. which are configured to cause one or more different gases to flow at different times and different regions. The gas and/or vacuum system may be connected to a first gas transport system that transports gas to and from the edge of the substrate 102 and controls the imprint field atmosphere by controlling the flow of gas at the edge of the substrate 102. The gas and/or vacuum system may be connected to a second gas transport system that transports gas to and from the edge of the template 108 and controls the imprint field atmosphere by controlling the flow of gas at the edge of the template 108. The gas and/or vacuum system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The shaping system 100 may be regulated, controlled, and/or directed by one or more processors 140 (controller) in communication with one or more components and/or subsystems such as the substrate chuck 104, the substrate positioning stage 106, the template chuck 118, the shaping head 120, the fluid dispenser 122, the radiation source 126, the thermal radiation source 134, the light source 135, the field camera 136, imprint field atmosphere control system, and/or the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The controller 140 may include a plurality of processors that are both included in the shaping system 100 and in communication with the shaping system 100. The processor 140 may be in communication with a networked computer 140a on which analysis is performed and control files such as a drop pattern are generated. In an embodiment, there are one or more graphical user interface (GUI) 141 on one or both of the networked computer 140a and a display in communication with the processor 140 which are presented to an operator and/or user.

Either the shaping head 120, the substrate positioning stage 106, or both varies a distance between the mold 110 and the substrate 102 to define a desired space (a bounded physical extent in three dimensions) that is filled with the formable material 124. For example, the shaping head 120 may apply a force to the template 108 such that mold 110 is in contact with the formable material 124. After the desired volume is filled with the formable material 124, the radiation source 126 produces actinic radiation (e.g., UV, 248 nm, 280 nm, 350 nm, 365 nm, 395 nm, 400 nm, 405 nm, 435 nm, etc.) causing formable material 124 to cure, solidify, and/or cross-link; conforming to a shape of the substrate surface 130 and the shaping surface 112, defining a patterned layer on the substrate 102. The formable material 124 is cured while the template 108 is in contact with formable material 124, forming the patterned layer on the substrate 102. Thus, the shaping system 100 uses a shaping process to form the patterned layer which has recesses and protrusions which are an inverse of the pattern in the shaping surface 112. In an alternative embodiment, the shaping system 100 uses a shaping process to form a planar layer with a featureless shaping surface 112.

The shaping process may be done repeatedly in a plurality of imprint fields (also known as just fields or shots) that are spread across the substrate surface 130. Each of the full field imprint fields may be the same size as the mesa 110 or just the pattern area of the mesa 110. The pattern area of the mesa 110 is a region of the shaping surface 112 which is used to imprint (shape) patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field (shaping field) which is the same size as the substrate 102 or the area of the substrate 102 which is to be patterned with the mesa 110. In an alternative embodiment, the imprint fields overlap. As noted above, some of the imprint fields may be partial imprint fields or small partial imprint fields which intersect with a boundary of the substrate 102.

The patterned layer may be formed such that it has a residual layer having a residual layer thickness (RLT) that is a minimum thickness of formable material 124 between the substrate surface 130 and the shaping surface 112 in each imprint field. The patterned layer may also include one or more features such as protrusions which extend above the residual layer having a thickness. These protrusions match the recesses 114 in the mesa 110.

### Template

FIG. 2A is an illustration of a template 108 (not to scale) that may be used in an embodiment. The shaping surface 112 may be on a mesa 110 (identified by the dashed box in FIG. 2A). The mesa 110 is surrounded by a recessed surface 244 on the front side of the template. The mesa 110 has a mesa height h_{T}. The mesa height h_{T} may between 1-200 μm. Mesa sidewalls 246 connect the recessed surface 244 to shaping surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles. FIG. 2B is a perspective view of the template 108 (not to scale) showing the mesa edges 210e. FIG. 2B illustrates that the intersection of the mesa sidewalls 246 and the recessed surface 244 may have some curvature due to the process of etching away material form a template precursor to form the mesa 110 on the template 108. The template 108 may have a square planar shape with a template width w_{T} as illustrated in FIGS. 2A-B. In an alternative embodiment, the template width w_{T} is a characteristic width and a planar shape of the template 108 may be a rectangle, parallelogram, polygon, or circle, or some other shape. The template width w_{T} may be between 10-450 mm.

### Imprinting/Planarizing Process

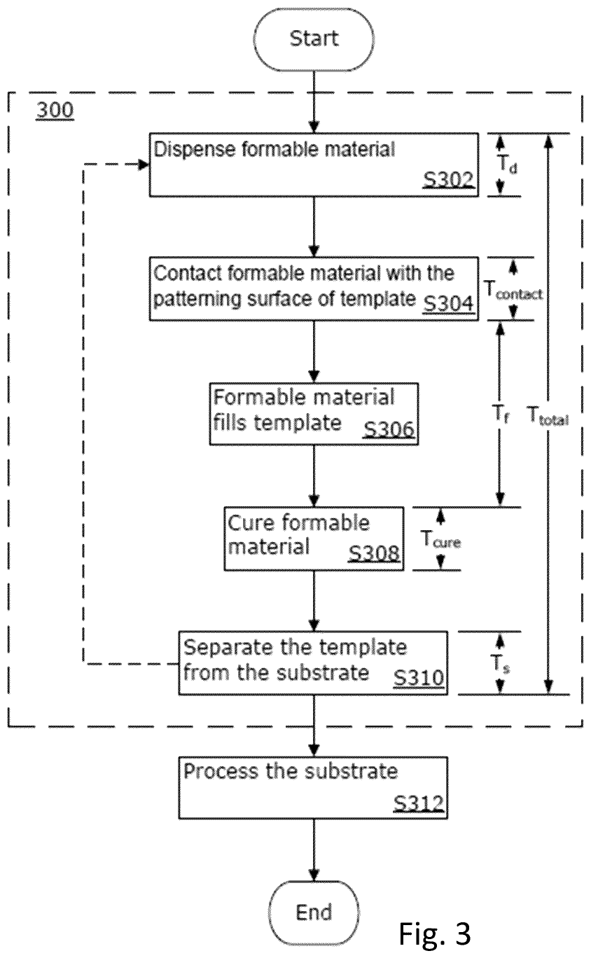

FIG. 3 is a flowchart of a method of manufacturing an article (device) that includes a shaping process 300 performed by the shaping system 100. The shaping process 300 can be used to form patterns in formable material 124 on one or more imprint fields (also referred to as: pattern areas or shot areas). The shaping process 300 may be performed repeatedly on a plurality of substrates 102 by the shaping system 100. The processor 140 may be used to control the shaping process 300.

In an alternative embodiment, the shaping process 300 is used to planarize the substrate 102. In which case, the shaping surface 112 is featureless and may also be the same size or larger than the substrate 102.

The beginning of the shaping process 300 may include a template mounting step causing a template conveyance mechanism to mount a template 108 onto the template chuck 118. The shaping process 300 may also include a substrate mounting step, the processor 140 may cause a substrate conveyance mechanism to mount the substrate 102 onto the substrate chuck 104. The substrate may have one or more coatings and/or structures. The order in which the template 108 and the substrate 102 are mounted onto the shaping system 100 is not particularly limited, and the template 108 and the substrate 102 may be mounted sequentially or simultaneously.

In a positioning step, the processor 140 may cause one or both of the substrate positioning stage 106 and/or a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by a shaping field index i. In which N is the number of shaping fields and is a real positive integer such as 1, 10, 62, 75, 84, 100, etc. {N∈ [symbol] ⁺}. In a dispensing step S302, the processor 140 may cause the fluid dispenser 122 to dispense formable material based on a drop pattern onto an imprinting field. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field may be moved relative to the fluid dispenser 122 while the fluid dispenser is ejecting formable material 124. Thus, the time at which some of the droplets land on the substrate may vary across the imprint field i. The dispensing step S302 may be performed during a dispensing period T_{d} for each imprint field i.

In an embodiment, during the dispensing step S302, the formable material 124 is dispensed onto the substrate 102 in accordance with a drop pattern. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets. Some know drop patterns are in the form of a grid where the drop positions are located at regular intervals in the X and Y dimensions. For example, grid drop patterns are disclosed in U.S. Pat. No. 11,215,921, which is hereby incorporated by reference in its entirety.

After, the droplets are dispensed, then a contacting step S304 may be initiated, the processor 140 may cause one or both of the substrate positioning stage 106 and a template positioning stage to bring the shaping surface 112 of the template 108 into contact with the formable material 124 in a particular imprint field. The contacting step S304 may be performed during a contacting period T_{contact} which starts after the dispensing period T_{d} and begins with the initial contact of the shaping surface 112 with the formable material 124. In an embodiment, by the beginning of the contact period T_{contact} the template chuck 118 is configured to bow out the template 108 so that only a portion of the shaping surface 112 is in contact with a portion of the formable material. In an embodiment, the contact period T_{contact} ends when the template 108 is no longer bowed out by the template chuck 118. The degree to which the shaping surface 112 is bowed out relative to the substrate surface 130 may be estimated with the spread camera 136.

During a filling step S306, the formable material 124 spreads out towards the edge of the imprint field and the mesa sidewalls 246. The edge of the imprint field may be defined by the mesa sidewalls 246. How the formable material 124 spreads and fills the mesa may be observed via the field camera 136 and may be used to track a progress of a fluid front of formable material. In an embodiment, the filling step S306 occurs during a filling period T_{f}. The filling period T_{f} begins when the contacting step S304 ends. The filling period T_{f} ends with the start of a curing period T_{c}. In an embodiment, during the filling period T_{f} the back pressure and the force applied to the template are held substantially constant. Substantially constant in the present context means that the back pressure variation and the force variation is within the control tolerances of the shaping system 100 which may be less 0.1% of the set point values.

In a curing step S308, the processor 140 may send instructions to the radiation source 126 to send a curing illumination pattern of actinic radiation through the template 108, the mesa 110, and the shaping surface 112 during a curing period T_{c}. The curing illumination pattern provides enough energy to cure (polymerize) the formable material 124 under the shaping surface 112. The curing period T_{c} is a period in which the formable material under the template receives actinic radiation with an intensity that is high enough to solidify (cure) the formable material. In an alternative embodiment, the formable material 124 is exposed to a gelling illumination pattern of actinic radiation before the curing period T_{c} which does not cure the formable material but does increase the viscosity of the formable material.

In a separation step S310, the processor 140 uses one or more of: the substrate chuck 104; the substrate positioning stage 106, template chuck 118, and the shaping head 120 to separate the shaping surface 112 of the template 108 from the cured formable material on the substrate 102 during a separation period Tₛ. If there are additional imprint fields to be imprinted, then the process moves back to step S302. In an alternative embodiment, during step S302 two or more imprint fields receive formable material 124 and the process moves back to steps S302 or S304.

In an embodiment, after the shaping process 300 is finished additional semiconductor manufacturing processing is performed on the substrate 102 in a processing step S312 so as to create an article of manufacture (e.g., semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, mounting, circuit board assembly, and the like. The substrate 102 may be processed to produce a plurality of articles (devices).

### Drop Pattern Generation

As part of an imprinting/planarizing process, a plurality of drops of formable material 124 are dispensed onto a substrate 102 which is then imprinted/planarized. Imprinting/planarizing may be done in a field-by-field basis or on a whole substrate basis. The drops of formable material 124 may also be deposited in a field-by-field basis or on a whole substrate basis. Even when the drops are deposited on a whole substrate basis generating the drop pattern is preferably done on a field-by-field basis.

Generating a drop pattern for a full field may include a processor 140 receiving a substrate pattern of a representative substrate 102, and a template pattern of a representative template 108.

The substrate pattern may include information about substrate topography of the representative substrate, a field of the representative substrate and/or a full field of the representative substrate. The substrate topography may be measured, generated based on previous fabrication steps and/or generated based on design data. In an alternative embodiment, the substrate pattern is featureless either because there were no previous fabrication steps or the substrate had previously been planarized to reduce topography. The substrate topography may include information about the shape such as a bevel, a rounding of an edge of the representative substrate. The substrate topography may include information about the shape and position of one or more flats or notches which identify the orientation of the substrate. The substrate topography may include information about a shape and position of a reference edge which surrounds the area of the substrate on which patterns are to be formed.

The template pattern may include information about the topography of the patterning surface 112 of the representative template. The topography of the patterning surface 112 may be measured and/or generated based on design data. In an alternative embodiment, the template pattern of the representative embodiment is featureless and may be used to planarize the substrate 102. The patterning surface 112 may be the same size as: an individual full field; multiple fields; the entire substrate, or larger than the substrate.

Once the substrate pattern and the template pattern are received, a processor 140 may calculate a distribution of formable material 124 that will produce a film that best fills the volume between the substrate and the patterning surface when the substrate and the patterning surface are separated by a gap during imprinting. The distribution of formable material on the substrate may take the form of: an areal density of formable material; positions of droplets of formable material; and/or volume of droplets of formable material. Calculating the distribution of formable material may take into account one or more of: material properties of the formable material, material properties of the patterning surface, material properties of the substrate surface, spatial variation in volume between the patterning surface and the substrate surface; fluid flow, evaporation; etc.

Preferably, the drop pattern generation method described herein, is beneficial for faster filling of relatively large features that are a subset of the features described above. For example, in certain area of the substrate there are alignment marks (also referred to as marks) that are used for alignment and/or overlay. Marks used in the art have various shapes and sizes but generally in the range of 10 to 100 μm in the X and Y direction and 0.1 to 0.2 μm in the Z direction (depth). When the shape of the mark is generally square or rectangle in cross section, the X and Y direction dimension of the mark may be considered the length and width and the Z direction dimension of the mark may be considered the depth. When the shape of the mark is not square or rectangular in cross section, the X and Y direction dimension of the mark may be considered the longest distance between two points in the X direction and the longest distance between two points in the Y direction, with the Z direction being the depth. In other word the volume of the mark may be in the range of 0.01 picoliters to 10 picoliters. Example marks include Archer marks, large bar-in-bar marks, through the mask (TTM) marks, box-in-box marks, small box marks, cross-in-cross type marks, grating type marks, checkerboard-grating type marks, bar-in-bar type marks, moiré type marks, bullseye marks, fiducial marks, pre-alignment marks, vernier type marks, combination marks, overlay marks, et al. In other cases, the method described herein may be applied to relatively large features that are not marks. These features that are not marks may have the same volume range as the marks listed above. Examples of these feature that are not marks are bond pads, interconnects, power lines, capacitor features, fluid control features, grounding features, etc.

### Method of Generating a Drop Pattern

A drop dispensing method by the nanoimprint lithography system 100 or planarization system can be used to dispense a pattern of drops of formable material 124 onto the substrate 102. The drop dispensing method described herein filling marks and large features more quickly than standard.

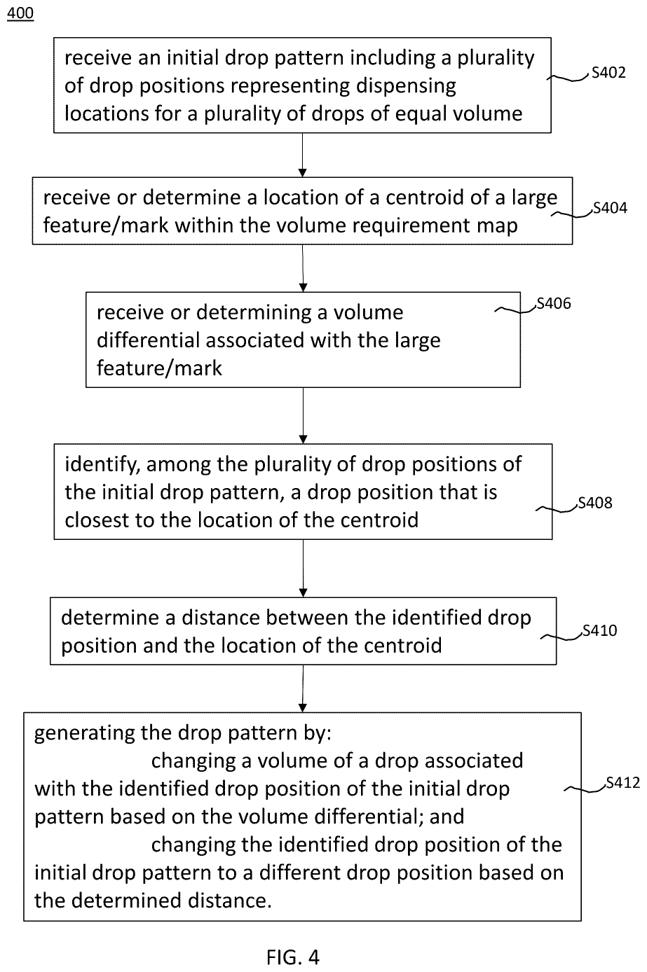

FIG. 4 is a flowchart illustrating a method of generating a drop pattern 400 in accordance with an example embodiment. The method 400 begins with step S402 where an initial drop pattern including a plurality of drop positions representing dispensing locations for a plurality of drops of equal volume is received. In another embodiment the initial drop pattern can be generated. The volume of each drop that correspond to the drop pattern may be 0.1 to 10 picoliters, where each drop volume is the same (equal). The initial drop pattern is based on a volume requirement map. The volume requirement map is based on the topography of the substrate, the template, and a desired residual layer thickness (RLT) between the substrate and template of the formable material to be patterned. The volume requirement map may take the form of a grid of tiles in which each tile represents a desired volume to be filled by a drop at a particular location. A single drop may fill 2-10,000 tiles depending on the underlying features. The underlying topography of the substrate and template have small features that are much smaller than a single tile and cover large areas (100-100,000 tiles), no features whatsoever, or large features that cover many tiles (5-100). More particularly, the volume requirement map is information regarding how much volume of formable material is needed to fill the features within the coordinate system of the map. That is, each feature within the map has a volume to be filled by formable material and the volume requirement map indicates the quantity and location of the volume. The features within the volume requirements map may be relatively small volume features or relatively large volume features, as defined above.

The initial drop pattern is the desired pattern of the drops to be dispensed onto the substrate. In other words, the initial drop pattern is a placement pattern that represents the predetermined ideal location of the drops on the substrate, using the data from the volume requirement map. More particularly, the initial drop pattern defines a predetermined location on a substrate for each droplet of a plurality of droplets. Each of the positions of the drops of the pattern may located at a particular coordinate within the area defined by the pattern. Receiving (or generating) an initial drop pattern may be performed using any known technique or future developed technique, as the drop pattern generating method described herein is independent of the particular manner in which the initial drop pattern is determined. That is, the drop dispensing method described herein can be performed using any preliminary drop pattern, regardless of how the drop pattern has been developed. Examples of generating a drop pattern that may be used as the initial drop pattern can be found in such documents as U.S. Pat. Nos. 8,119,052; 8,512,797; 8,586,126; 8,691,123; 9,415,418; 9,718,096; and 11,209,730; and U.S. Pat. App. Pub. Nos.: 2010/0101493; and 2017/0140922. That is, the drop pattern determined from the methods described in these documents (or any other drop pattern) may serve as the step of providing an initial drop pattern. In an embodiment, the initial drop pattern is a grid drop pattern where the drop positions are located at regular intervals in the X and Y dimensions, as described in U.S. Pat. No. 11,215,921.

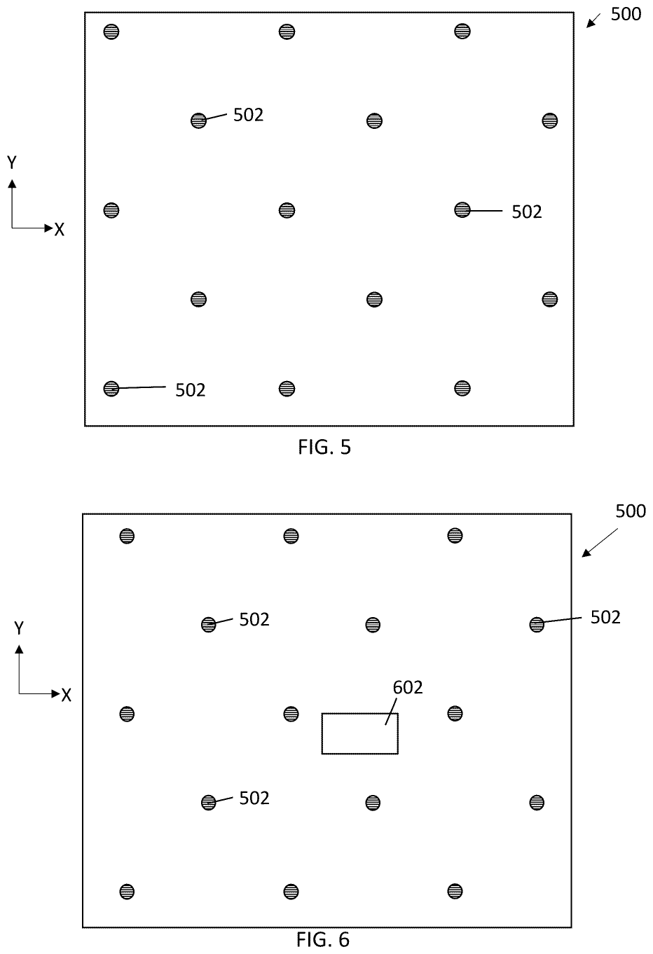

FIG. 5 is a schematic representation of an example initial drop pattern 500. The example initial drop pattern of FIG. 5 is a grid drop pattern, where the drop positions are located at regular intervals in the X and Y dimensions. As shown in FIG. 5, the initial drop pattern 500 comprises a plurality of drop positions 502. Any number of drop positions can be located throughout the X-Y area depending on the particular application. As discussed above, any known method may be used to arrive at a particular initial drop pattern 500. The initial drop pattern 500 essentially represents the desired location of the plurality of drops on the substrate 102 based on the information from the volume requirement map.

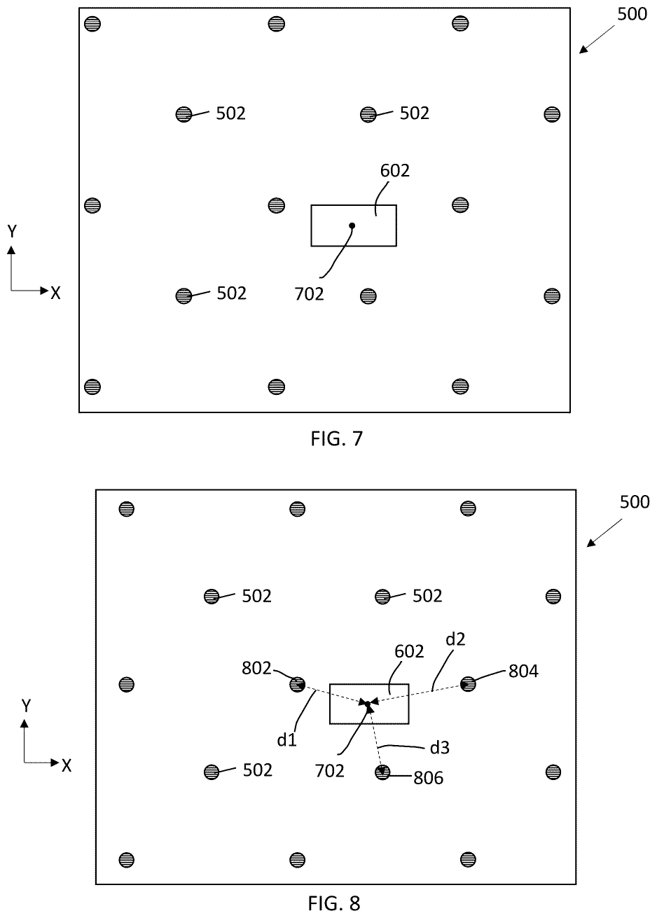

Once the initial drop pattern has been provided, the method may proceed to step S504, where a location of a centroid of a large feature/mark within the volume requirement is received or determined. As noted above, a large feature may be any feature that has the above-noted fill volume requirement, i.e., 0.01 to 10 picoliters. Preferably, the large feature is one or more of the marks discussed above. The location of large feature/mark relative to drop pattern is first identified by for example analyzing the volume requirement map or based on information supplied along with the volume requirement map in which the marks/features are identified. For example, the volume requirement map can include a plurality of N tiles arranged on a regular grid identified each tile identified by for example an index j. Each tile j having several values associated with it, for example the volume requirement map could include: an x position (xⱼ) of each tile j; a y position (yⱼ) of each tile j; a tile volume (vⱼ) of each tile j; an area (Aⱼ) of each tile j; a probability of flow in the x direction (fxⱼ) of each tile j; a probability of flow in the y direction (fyⱼ) of each tile j; etc. The volume requirement map can be analyzed to identify marks/features. Analyzing the volume requirement map can include performing a connected feature analysis on a set N volume values vⱼ to identify a feature subset k of 2 to 1000 tiles that are part of a feature/mark. This analysis of the volume requirement map can be done using for example one or more of the connected component functions in the imgproc module of the OpenCV library from the OpenCV Team of Palo Alto, CA to identify the feature subset k of tiles. Analyzing the volume requirement map to identify large features/marks can include performing a filtering step on the volume requirement map. Analyzing the volume requirement map to identify large features/marks can include performing thresholding to create a binary volume requirement map. Analyzing the volume requirement map to identify large features can include taking the results of the connected component functions and identifying features that are within a range of sizes that have less volume than a single drop. Every feature that was not accommodated in the initial drop pattern 500 with a volume greater than 0.01 pL can be considered to be a large feature. FIG. 6 shows a schematic representation of the initial drop pattern 500 with a large feature/mark 602 having been identified. After identifying the location of the large feature/mark 602, the centroid of the large feature/mark 602 is determined. The centroid of the large feature/mark is the geometric center of the large feature/mark. The centroid may be determined by analyzing a volume requirement map once the subset of k tiles are identified using a process such as the one described above, the centroid coordinates (X_{centroid}, Y_{centroid}) can then be calculated using for example a weighted average of the tile volume as described in equation (1) below. FIG. 7 shows a schematic representation of the initial drop pattern 500 with the centroid 702 of the large feature/mark 602 having been identified.

$${X}_{centroid} = {\sum }_{j ∈ k} {x}_{j} {v}_{j} / {\sum }_{j ∈ k} {v}_{j} \qquad ( 1 )$$

$${Y}_{centroid} = {\sum }_{j ∈ k} {y}_{j} {v}_{j} / {\sum }_{j ∈ k} {v}_{j}$$

After the centroid 702 of the large feature/mark 602 has been received or determined, the method may proceed to step S406, where a volume differential associated with the large feature/mark is received or determined. Ideally, the volume differential is a volume amount that is the difference between the fill volume of the large feature/mark 602 and the amount of the volume of the large feature/mark 602 that would have been filled if drops were dispensed according to the initial drop pattern 500 at a particular set filling time. In other words, if, for example, the filling time is set at 0.5 seconds, the volume differential would be the difference between the fill volume of the large feature/mark and the amount of volume of the large feature/mark that is filled when dispensing drops according to the initial drop pattern and then allowing for 0.5 seconds of fill time.

The fill volume of the large feature/mark is known as discussed above, i.e., from the known volume of the large feature/mark. The amount of volume of the large feature/mark that would be filled by dispensing drops according to the initial drop pattern at the particular filling time can be directly measured or approximated. In the case of directly measuring, drops can be dispensed according to the initial drop pattern and the amount of volume that is filled after the particular filling time (e.g., 0.5 seconds) can be measured. In the case of approximating the volume amount that the large feature/mark would be filled within the particular filling time using the initial drop pattern, the approximation can be made in several ways. For example, the approximation can be made by using an average volume around the large feature/mark. The feature subset k that includes the large feature/mark includes K tiles. The processor can identify a neighboring subset m of tiles that are immediately adjacent to the tiles in the feature subset k. The neighboring subset m includes M tiles. The neighboring subset m can include 1-100 rings of tiles surrounding the feature subset k of tiles. A processor can be used to estimate an average local fill volume per unit area (for example a tile area or some other representative area if the tiles are not uniform in area) by calculating a statistical measure of central tendency (mean, median, mode, geometric mean, harmonic mean, trimmed mean, trimmed median, etc.) among the tile volumes of the tiles (vₘ={vⱼ}_{j∈m}) in the neighboring subset m. The processor can then calculate the fill volume associated with dispensing the plurality of drops of the feature (v₀) by multiplying the statistical measure of central tendency by an estimated area of the feature according to the initial drop pattern average local fill volume per unit area times the area of the feature. Equation (2) below is an example how this calculation of v₀ can be performed when an average is used as the statistical measure and the tiles are uniform in size. The volume differential (Vd) can then also be calculated by the processor by calculating a difference between a sum of all the volumes (vₖ={vⱼ}_{j∈k}) associated with tiles of the in the feature subset and the fill volume associated with dispensing the plurality of drops of the feature (V₀) as described in equation (3) below. In another example, the approximate fill volume associated with dispensing the plurality of drops according to the initial drop pattern can be made by equating the RLT around the feature times an area of the feature. Other options for making the approximation are receiving the Information from outside database based on the design of the template and the desired RLT. When the volume differential is based on the approximate amount of filling of the large feature/mark, the volume differential is an estimated volume differential. The volume differential may be 0% of the fill volume of the large feature/mark to 95% of the fill volume of the large feature/mark. The volume differential may be 0.0005 picoliters to 1 picoliters in an example embodiment.

$${v}_{0} = K ( \frac{1}{M} {\sum }_{j ∈ m} {v}_{j} ) \qquad ( 2 )$$

$$Vd = {\sum }_{j ∈ k} {v}_{j} - {v}_{0} \qquad ( 3 )$$

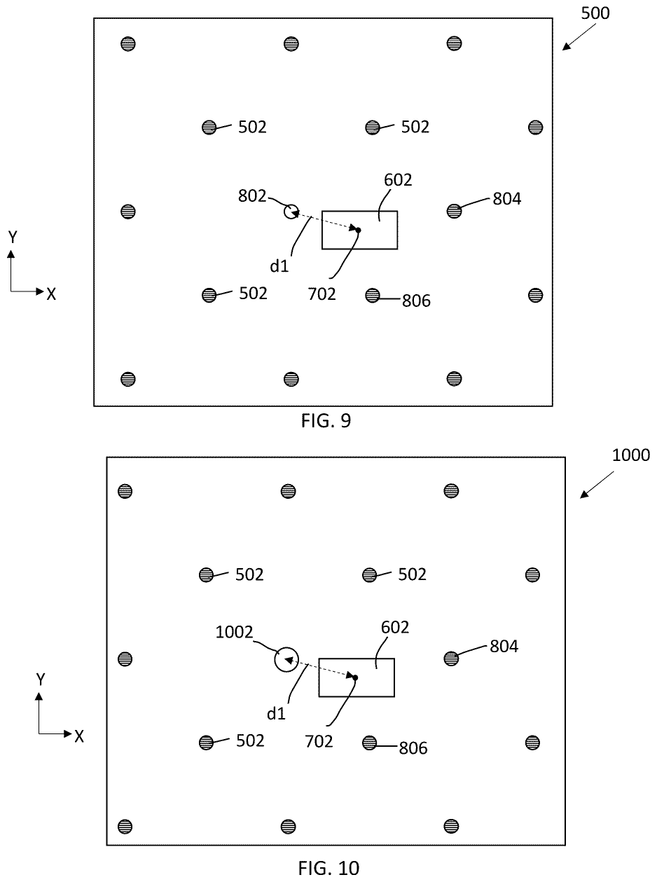

After receiving or determining the volume differential, the method 400 may proceed to step S408 where, among the plurality of drop positions of the initial drop pattern, a drop position that is closest to the location of the centroid is identified. The drop position in the initial drop pattern that is closest to the centroid is identified by measuring the linear distance from each of the drop positions. The drop position that has the smallest linear distance from the centroid is the closest drop position. The location of the drop position is defined as the center of the drop. FIG. 8 is a schematic representation of the example initial drop pattern 500 in which example distances d1, d2, and d3, between the centroid 702 and three example drop positions 802, 804, 806 are illustrated. The distances are calculated based on the planar Euclidean distance in the x-y plane between the center of the drop and the centroid. As shown in FIG. 8, the distance between the centroid 702 and the drop position 802 is the smaller than the distance d2 between the centroid 702 and the drop position 804. While close, the distance d1 is also slightly smaller than the distance d3 between the centroid 702 and the drop position 806. In this example, the distances between the drop positions 802, 804, 806 and the centroid 702 illustrated as examples because they are visibly the closest to the centroid 702. However, the distances between each drop of the initial drop pattern and the centroid 702 can be determined. FIG. 9 is a schematic representation of the example initial drop pattern 500 in which the closest drop position 802 has been identified as indicated by the drop position 802 lacking any crosshatching. In case where more than one drop position in the initial drop pattern has identical distance from the centroid, the identified drop may be randomly chosen among them. The identified drop may also be selected based on relative distances that are adjusted based on a sum of the relative probabilities of flow f of tiles between the drop positions and the centroid of the feature.

As part of performing step S408, the step S410 of determining a distance between the identified drop position and the location of the centroid has already been performed. That is, as discussed above, as part of the process of identifying the closest drop position to the centroid, the distance between the drop positions and the centroid is measured. Thus, the distance between the identified drop and the centroid is known after completing the process of identifying the closest drop position to the centroid. In the example shown in FIG. 8, the determined distance is d1. The distance d1 may be from 0.1%-50% of a pitch of a local grid of drops surrounding the feature in the initial drop pattern.

With the volume of the drops to be dispensed known, the volume differential known, the closest drop position to the centroid known, and the distance between the closest drop position and the centroid known, the method may proceed to step S412 where the drop pattern is generated. As part of step S412, the drop pattern is generated by 1) changing a volume of a drop associated with the identified drop position of the initial drop pattern based on the volume differential and 2) changing the identified drop position of the initial drop pattern to a different drop position based on the determined distance. In other words, the initial drop pattern is modified by changing the volume of the identified drop position and moving the location of the identified drop position, thereby generating the improved drop pattern.

FIG. 10 is a schematic representation of a modified initial drop pattern 1000 in which the volume of the identified drop position 1002 has been changed as compared to the initial drop pattern 500. The drop position 1002 corresponds to the identified drop position 802 in FIGS. 8 and 9. As shown in FIG. 10, the identified drop position 1002 has a larger circle than the identified drop position 802, indicating that the volume of the drop to be dispensed has increased. The amount of the increase is based on the volume differential received or determined in step S406. More specifically, in the case that Vi represents the volume of the drop to be dispensed according to the initial drop pattern at the identified drop position 502, Vd represents the volume differential, and Vf represents the volume of the corresponding identified drop position 1002 in the modified drop pattern of FIG. 10, then Vf=Vi+Vd. In an example embodiment Vi is 0.1 to 10 picoliters and Vd is 0.01 to 10 picoliters, with Vf being 1.01 to 20 picoliters. In an embodiment, Vd is in the 1%-100% of Vi.

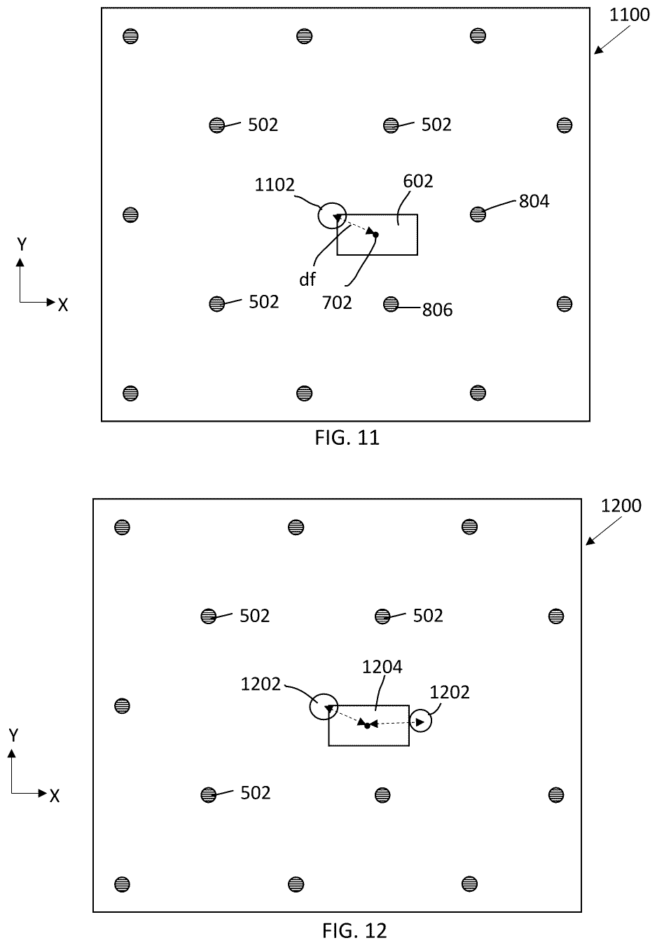

FIG. 11 is a schematic representation of a generated drop pattern 1100 in which distance df between the identified drop position 1102 and the centroid 702 has been changed as compared to the distance between the identified drop position and the centroid in the initial drop pattern 500. The drop position 1102 corresponds to the identified drop position 802 in FIGS. 8 and 9. As shown in FIG. 11, the identified drop position 1102 has a smaller distance df from the centroid 702 than the distance d1 between the identified drop position 802 and the centroid 702. That is, the position of the identified drop position 1102 in the modified drop pattern 1100 is closer to the centroid 702 than the identified drop position 802 of the initial drop pattern 500. The amount of the change (i.e., the difference between d1 and df) may be based on the distance d1, the modified drop volume Vf, and the volume differential Vd. In general, the greater the distance d1 the more the distance will need to be decreased, while the greater the final Vf the less the distance will need to be decreased to achieve sufficient filling within the desired filling time. The distance df can be determined experimentally by dispensing drops according to the modified drop pattern at different distances df and measuring the fill results within a set period of fill time (e.g., 0.5 seconds). The distance df can be determined through simulation using software that simulates filling over a set period of time for a drop pattern. Using either method, the resulting data can be used to generate a predictive model in which the original distance d1 and the final volume Vf can be correlated with the modified distance df that will provide desired filling performance. In an example embodiment the difference between distances d1 and df may be 0.1% to 100% of a distance between drops in the initial drop pattern.

The method of generating the drop pattern may further include repeating the same steps for multiple drop positions of the initial drop pattern near the same feature/mark and/or may include repeating the same steps for multiple (or all) relatively large features/marks within the volume requirement map. For example, the same process of changing the volume and moving the drop position from the initial drop pattern for one or more additional drop positions nearby (i.e., within a threshold distance from) the large feature/mark may be performed. In the case of the example drop pattern 500, the drop position 804 and/or the or the drop position 806 could also be moved closer to the centroid 702 and the volume of the drop can be increased. Furthermore, if there are multiple large features/marks within the volume requirements map, then same process can be performed for drop positions closest to those large features/mark. Thus, the final generated drop pattern could have many drop positions that have been relocated and which have larger drop volumes assigned.

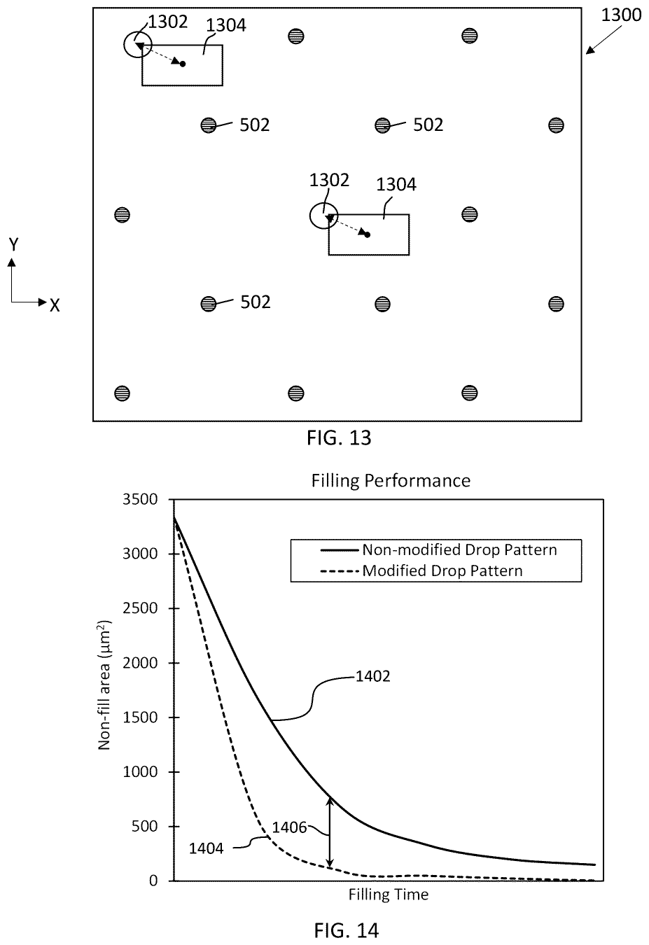

After the drop pattern 1100 has been generated according to the method 400, the shaping process 300 described above may be performed using the drop pattern 1100. That is, the same steps described above with respect to FIG. 3 may be performed where in step S302 the drops are dispensed according to the drop pattern 1100 that resulted from the drop pattern generation method of FIG. 4. This includes all of the steps in FIG. 3. Thus, a method of dispensing drops may include dispensing the drops according to the generated drop pattern, and a method of manufacturing an article may include the above-noted processing steps that follow the dispensing of the drops according to the generated drop pattern. FIG. 12 shows is a schematic representation of an example generated drop pattern 1200 in which multiple drop positions 1202 around the same large feature/mark 1204 have been changed relative to the initial drop pattern and whose associated drop volume has been increased. FIG. 13 shows is a schematic representation of an example generated drop pattern 1300 in which multiple drop positions 1302 around multiple large features/marks 1304 have been changed relative to the initial drop pattern and whose associated drop volume has been increased.

FIG. 14 is a chart showing the filling performance of drops dispensed according to an initial drop pattern without modification (i.e., a conventional drop pattern) as compared to filling performance of drops dispensed according to the drop pattern generated following the method 400 disclosed herein. The initial drop pattern filling performance is represented by line 1402 and the generated drop pattern following the method 400 is represented by the line 1404. The results are simulated using physics based simulation that takes fluid dynamics of the spread of fluid into account. All of the parameters in the simulations are maintained constant except for the change in the drop patterns. As shown in FIG. 14, the area of feature that is not filled by the in a fixed fill time using the initial drop pattern is decreased by an amount 1406 for the drop pattern generated using the method 400. Thus, by generating a drop pattern following the method 400, a reduction in fill time of 30-0.5 seconds can be achieved as compared to the initial drop pattern. This corresponds to an improvement in throughput of the shaping system 100 and an improvement in residual layer thickness uniformity. By dispensing drops according to the drop pattern generated following the method 400, the fill time for filling the same features may be from 10% to 75% of a reference time t it would take to fill the same features using the initial drop pattern. In other words, when t is the reference time it would take to fill the features using the initial drop pattern, the fill time it would take to fill the same features using the drop pattern generated following method 400 may be 0.1t to 0.75t.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method of generating a drop pattern comprising:
receiving an initial drop pattern including a plurality of drop positions representing dispensing locations for a plurality of drops of equal volume, wherein the initial drop pattern is based on a volume requirement map;
receiving or determining a location of a centroid of a feature within the volume requirement map;
receiving or determining a volume differential between a fill volume requirement of the feature and a fill volume associated with dispensing the plurality of drops according to the initial drop pattern;
identifying, among the plurality of drop positions of the initial drop pattern, a drop position that is closest to the location of the centroid;
determining a distance between the identified drop position and the location of the centroid; and
generating the drop pattern by:
changing a volume of a drop associated with the identified drop position of the initial drop pattern based on the volume differential; and
changing the identified drop position of the initial drop pattern to a different drop position based on the determined distance.

2. The method of generating a drop pattern of claim 1, wherein the fill volume requirement of the feature is from 0.01 picoliters to 10 picoliters.

3. The method of generating a drop pattern of claim 1, wherein the feature is an alignment mark.

4. The method of generating a drop pattern of claim 3, wherein the alignment mark is selected from the group consisting of box-in-box type, cross-in-cross type, grating type, checkerboard-grating type, bar-in-bar type, moiré type, bullseye, fiducial marks, pre-alignment marks, vernier type marks, combination marks, overlay marks.

5. The method of generating a drop pattern of claim 1, wherein the fill volume associated with dispensing the plurality of drops according to the initial drop pattern is an average local fill volume per unit area around the feature multiplied by an area of the feature.

6. The method of generating a drop pattern of claim 1, wherein the fill volume associated with dispensing the plurality of drops according to the initial drop pattern is a residual layer thickness multiplied by an area of the feature.

7. The method of generating a drop pattern of claim 1, wherein the fill volume associated with dispensing the plurality of drops according to the initial drop pattern is a volume that the feature is filled with in the case of dispensing the plurality of drops according to the initial drop pattern.

8. The method of generating a drop pattern of claim 1, wherein the changing of the volume of the drop comprises increasing the volume of the drop.

9. The method of generating a drop pattern of claim 1, wherein the different drop position is closer to the centroid than the identified drop position.

10. The method of generating a drop pattern of claim 1, wherein the difference between the initial drop pattern position of the identified drop and the different drop pattern position of the identified drop is 0.1-50% of a pitch of a local grid of drops surrounding the feature in the initial drop pattern.

11. The method of generating a drop pattern of claim 1, wherein volume differential is 0.01 to 1 picoliter.

12. The method of generating a drop pattern of claim 1, wherein the equal volume is 0.1 to 10 picoliters.

13. The method of generating a drop pattern of claim 12, further comprising:
receiving or determining a location of a centroid of a second feature within the volume requirement map;
receiving or determining a second volume differential between a fill volume requirement of the second feature and the fill volume associated with dispensing the plurality of drops according to the initial drop pattern;
identifying, among the plurality of drop positions of the initial drop pattern, a second drop position that is closest to the location of the centroid of the second feature;
determining a second distance between the identified second drop position and the location of the centroid of the second feature; and
generating the drop pattern by:
changing a volume of a drop associated with the identified second drop position of the initial drop pattern based on the second volume differential; and
changing the identified second drop position of the initial drop pattern to a different drop position based on the determined second distance.

14. The method of generating a drop pattern of claim 1, further comprising:
identifying, among the plurality of drop positions of the initial drop pattern, a second drop position within a threshold distance from the location of the centroid of the second feature;
determining a second distance between the identified second drop position and the location of the centroid of the feature; and
generating the drop pattern by:
changing a volume of a drop associated with the identified second drop position of the initial drop pattern based on the volume differential; and
changing the identified second drop position of the initial drop pattern to a different drop position based on the determined second distance.

15. The method of generating a drop pattern of claim 14, wherein the determined second distance is equal to or greater than the determined distance between the identified drop position and the location of the centroid.

16. The method of generating a drop pattern of claim 1, wherein the initial drop pattern is a grid drop pattern.

17. A method of shaping formable material, comprising:
dispensing a plurality of drops of formable material onto a substrate according to a drop pattern generated by the method of generating a drop pattern of claim 1; and
contacting a template or a superstrate with the dispensed drops.

18. The method of shaping formable material of claim 17,
wherein a fill time that the drops dispensed according to the generated drop pattern take to fill features on the substrate is 0.1t to 0.75t, and
wherein t is a reference time that drops dispensed according to the initial drop pattern take to fill the features on the substrate.

19. A shaping system, comprising:
a first chuck configured to hold a template or superstrate;
a second chuck configured to hold a substrate;
a processor configured to:
receive an initial drop pattern including a plurality of drop positions representing dispensing locations for a plurality of drops of equal volume, wherein the initial drop pattern is based on a volume requirement map;
receive or determine a location of a centroid of a feature within the volume requirement map;
receive or determine a volume differential between a fill volume requirement of the feature and a fill volume associated with dispensing the plurality of drops according to the initial drop pattern;
identify, among the plurality of drop positions of the initial drop pattern, a drop position that is closest to the location of the centroid;
determine a distance between the identified drop position and the location of the centroid; and
generate the drop pattern by:
changing a volume of a drop associated with the identified drop position of the initial drop pattern based on the volume differential; and
changing the identified drop position of the initial drop pattern to a different drop position based on the determined distance;
a fluid dispenser configured to dispense drops of formable material on the substrate in accordance with the generated drop pattern;
a positioning system configured to bring a template or a superstrate into contact with the formable material; and
a curing system configured to expose the formable material under the template or superstrate to actinic radiation.

20. A method of making an article, comprising:
receiving an initial drop pattern including a plurality of drop positions representing dispensing locations for a plurality of drops of equal volume, wherein the initial drop pattern is based on a volume requirement map;
receiving or determining a location of a centroid of a feature within the volume requirement map;
receiving or determining a volume differential between a fill volume requirement of the feature and a fill volume associated with dispensing the plurality of drops according to the initial drop pattern;
identifying, among the plurality of drop positions of the initial drop pattern, a drop position that is closest to the location of the centroid;
determining a distance between the identified drop position and the location of the centroid; and
generating the drop pattern by:
changing a volume of a drop associated with the identified drop position of the initial drop pattern based on the volume differential; and
changing the identified drop position of the initial drop pattern to a different drop position based on the determined distance;
dispensing drops of formable material onto a substrate according to the modified drop pattern;
bringing a template or superstrate into contact with the formable material;
exposing the formable material under the template or superstrate to actinic radiation;
processing the substrate; and
forming the article from the processed substrate.
